(19) United States
(12) Patent Application Publication
(10) Pub. No.: US 2024/0291267 A1
(43) Pub. Date: Aug. 29, 2024

(54) DISCHARGE CONTROL CIRCUIT

(71) Applicant: LAPIS Technology Co., Ltd., Yokohama (JP)

(72) Inventor: Takatsugu KAI, Yokohama (JP)

(73) Assignee: LAPIS Technology Co., Ltd., Yokohama (JP)

(21) Appl. No.: 18/581,291

(22) Filed: Feb. 19, 2024

(30) Foreign Application Priority Data
Feb. 27, 2023 (JP) 2023-028965

(51) Int. Cl. H02H 9/00; H03K 5/24; H03K 17/0812; H03K 17/16

(52) U.S. Cl. CPC H02H 9/002; H03K 5/2481; H03K 17/08122; H03K 17/162

(57) ABSTRACT

The disclosure suppresses an inrush current generated due to discharge of a capacitive load at low cost. A discharge control circuit includes: a first gate voltage output circuit that outputs a first gate voltage supplied to a transistor connected to a capacitive load; a second gate voltage output circuit that outputs a second gate voltage supplied to the transistor; and a switching control circuit that switches supply of the first gate voltage and the second gate voltage to the transistor. The first gate voltage output circuit controls the first gate voltage so that a current flowing through the transistor is constant. The second gate voltage output circuit outputs a voltage at a constant level as the second gate voltage. The switching control circuit performs control to supply the second gate voltage after supplying the first gate voltage to the transistor.

### CROSS-REFERENCE TO RELATED APPLICATION

This application claims the priority benefits of Japanese application no. 2023-028965, filed on Feb. 27, 2023. The entirety of the above-mentioned patent application is hereby incorporated by reference herein and made a part of this specification.

### BACKGROUND

### Technical Field

The disclosed technology relates to a discharge control circuit.

### Description of Related Art

The following techniques are known as techniques for suppressing an inrush current when power is turned on. For example, Patent Document 1 (Japanese Patent Application Laid-Open No. 2002-116828) describes an inrush current suppression circuit that switches the method of controlling a control voltage supplied to an inrush current suppression transistor depending on whether or not the inrush current has finished flowing, supplies the inrush current suppression transistor with a control voltage within a range where the internal resistance of the inrush current suppression transistor can suppress the inrush current while the inrush current is flowing, and supplies the inrush current suppression transistor with a control voltage so that the internal resistance of the inrush current suppression transistor has a sufficiently low value after the inrush current has finished flowing.

Patent Document 2 (Japanese Patent Application Laid-Open No. 1-175614) describes a voltage stabilizing circuit that includes a field effect transistor whose source terminal is connected to the negative polarity side of an input power supply and whose drain terminal is connected to the negative polarity side of a load, a comparator that compares the voltage supplied to the load with a reference voltage, a voltage amplifier that amplifies the output voltage of the comparator and provides the output voltage to the gate terminal of the field effect transistor, a current transformer in which a primary winding is formed between the source terminal of the field effect transistor and the negative polarity terminal of the input power supply and one end of a secondary winding that generates a voltage in the negative direction due to the current flowing through the primary winding is connected to the gate terminal of the field effect transistor, and a voltage switching circuit that clamps the gate voltage of the field effect transistor to a constant value with the input voltage of the input power supply.

The power supply to a capacitive load is controlled by turning on/off a transistor provided between the capacitive load and a power supply. When the transistor is switched from the off state to the on state, an inrush current flows in the power supply path as the charge accumulated in the capacitive load is discharged. An excessive inrush current may damage the load system.

As a countermeasure, a conceivable method is to provide a first discharge path including a current limiting resistor and a second discharge path not including a current limiting resistor, and to connect the capacitive load to the first discharge path to apply a discharge current to the first discharge path during a pre-discharge period immediately after power starts to be supplied to the capacitive load, and to connect the capacitive load to the second discharge path to supply power to the capacitive load using the second discharge path with low resistance during a subsequent discharge period. According to this method, however, a transistor is required for each of the first discharge path and the second discharge path to switch connection/disconnection with the capacitive load, which leads to an increase in cost.

The disclosed technology suppresses an inrush current generated due to discharge of a capacitive load at low cost.

### SUMMARY

A discharge control circuit according to the disclosed technology includes: a first gate voltage output circuit configured to output a first gate voltage supplied to a transistor connected to a capacitive load; a second gate voltage output circuit configured to output a second gate voltage supplied to the transistor; and a switching control circuit configured to switch supply of the first gate voltage and the second gate voltage to the transistor. The first gate voltage output circuit is configured to control the first gate voltage so that a current flowing through the transistor is constant. The second gate voltage output circuit is configured to output a voltage at a constant level as the second gate voltage. The switching control circuit is configured to perform control to supply the second gate voltage after supplying the first gate voltage to the transistor.

### BRIEF DESCRIPTION OF THE DRAWINGS

FIG. 1 is a diagram showing an example of the configuration of the load driving system 1 including the discharge control circuit according to an embodiment of the disclosed technology.

FIG. 2 is a diagram showing the operation waveforms of various parts obtained by an operation simulation performed on the load driving system according to an embodiment of the disclosed technology.

FIG. 3 is a diagram showing an example of the configuration of the load driving system according to a comparative example.

FIG. 4 is a diagram showing the operation waveforms of various parts obtained by an operation simulation performed on the load driving system according to a comparative example.

### DESCRIPTION OF THE EMBODIMENTS

An example of the embodiment of the disclosed technology will be described below with reference to the drawings. In addition, the same reference numerals are assigned to the same or equivalent components and parts in each drawing, and repeated description will be omitted.

The disclosed technology is capable of suppressing an inrush current generated due to discharge of a capacitive load at low cost.

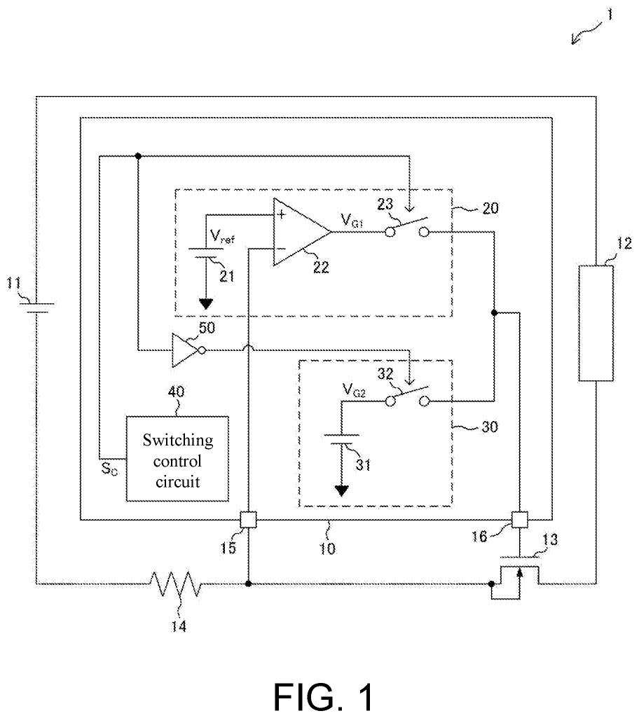

FIG. 1 is a diagram showing an example of the configuration of a load driving system 1 including a discharge control circuit 10 according to an embodiment of the disclosed technology. The load driving system 1 includes a power supply 11, a capacitive load 12, a transistor 13, and a current detection resistor 14 as components other than the discharge control circuit 10. The load driving system 1 is a system that controls power supply to the capacitive load 12 by turning on/off the transistor 13.

The capacitive load 12 has one end connected to the positive electrode of the power supply 11 and the other end connected to the drain of the transistor 13. The transistor 13 is, for example, a field effect transistor, and has the drain connected to the capacitive load 12, the source connected to one end of the current detection resistor 14, and the gate connected to a gate voltage output terminal 16 of the discharge control circuit 10. The current detection resistor 14 has one end connected to the source of the transistor 13 and the other end connected to the negative electrode of the power supply 11. A connection point between the source of the transistor 13 and the current detection resistor 14 is connected to a current detection terminal 15 of the discharge control circuit 10. When the transistor 13 is set to the on state, the capacitive load 12 and the power supply 11 are connected, and power is supplied to the capacitive load 12. At this time, a discharge current accompanying discharge of the charge accumulated in the capacitive load 12 flows through the transistor 13 and the current detection resistor 14.

The discharge control circuit 10 has a function of suppressing an inrush current that flows into the power supply path due to discharge of the capacitive load 12 when power is supplied to the capacitive load 12. The discharge control circuit 10 is composed of an integrated circuit provided on a semiconductor substrate. The discharge control circuit 10 includes a first gate voltage output circuit 20, a second gate voltage output circuit 30, a switching control circuit 40, and an inverter 50.

The first gate voltage output circuit 20 includes a reference voltage source 21, a differential amplifier circuit 22, and a first switch 23. The differential amplifier circuit 22 has the non-inverting input terminal connected to the reference voltage source 21, the inverting input terminal connected to the current detection resistor 14 via the current detection terminal 15, and the output terminal connected to one end of the first switch 23. The reference voltage source 21 outputs a reference voltage V_{ref} that is input to the non-inverting input terminal of the differential amplifier circuit 22. The first switch 23 is composed of a semiconductor element such as a transistor, and has one end connected to the output terminal of the differential amplifier circuit 22 and the other end connected to the gate of the transistor 13 via the gate voltage output terminal 16.

The first switch 23 is turned on/off according to a control signal S_{C} supplied from the switching control circuit 40. By setting the first switch 23 to the on state, the output voltage of the differential amplifier circuit 22 is supplied to the gate of the transistor 13 as a first gate voltage V_{G1}. The first gate voltage output circuit 20 controls the first gate voltage V_{G1} so that the difference between the terminal voltage of the current detection resistor 14 input to the current detection terminal 15 and the reference voltage V_{ref} is constant. In other words, the first gate voltage output circuit 20 controls the first gate voltage V_{G1} so that the current flowing through the transistor 13 is constant.

The second gate voltage output circuit 30 includes a constant voltage source 31 and a second switch 32. The second switch 32 has one end connected to the constant voltage source 31 and the other end connected to the gate of the transistor 13 via the gate voltage output terminal 16. The second switch 32 is turned on/off according to the control signal S_{C} supplied from the switching control circuit 40. By setting the second switch 32 to the on state, the output voltage of the constant voltage source 31 whose voltage level is constant is output as a second gate voltage V_{G2}, and is supplied to the gate of the transistor 13.

The switching control circuit 40 switches the supply of the first gate voltage V_{G1} and the second gate voltage V_{G2} to the transistor 13. The switching control of the switching control circuit 40 is performed based on the control signal S_{C}. The first switch 23 is supplied with the control signal S_{C} directly, and the second switch 32 is supplied with the control signal S_{C} whose logic has been inverted by the inverter 50. Thus, the first switch 23 and the second switch 32 are turned on/off in a complementary manner. That is, when the first switch 23 is set to the on state, the second switch 32 is set to the off state, and when the first switch 23 is set to the off state, the second switch 32 is set to the on state.

The switching control circuit 40 performs control to supply the first gate voltage V_{G1} to the transistor 13 by setting the first switch 23 to the on state when power is supplied to the capacitive load 12, and then supply the second gate voltage V_{G2} to the transistor 13 by setting the second switch 32 to the on state. The switching control circuit 40 may, for example, perform control to supply the second gate voltage V_{G2} to the transistor 13 after a predetermined period has elapsed since the start of supply of the first gate voltage V_{G1} to the transistor 13.

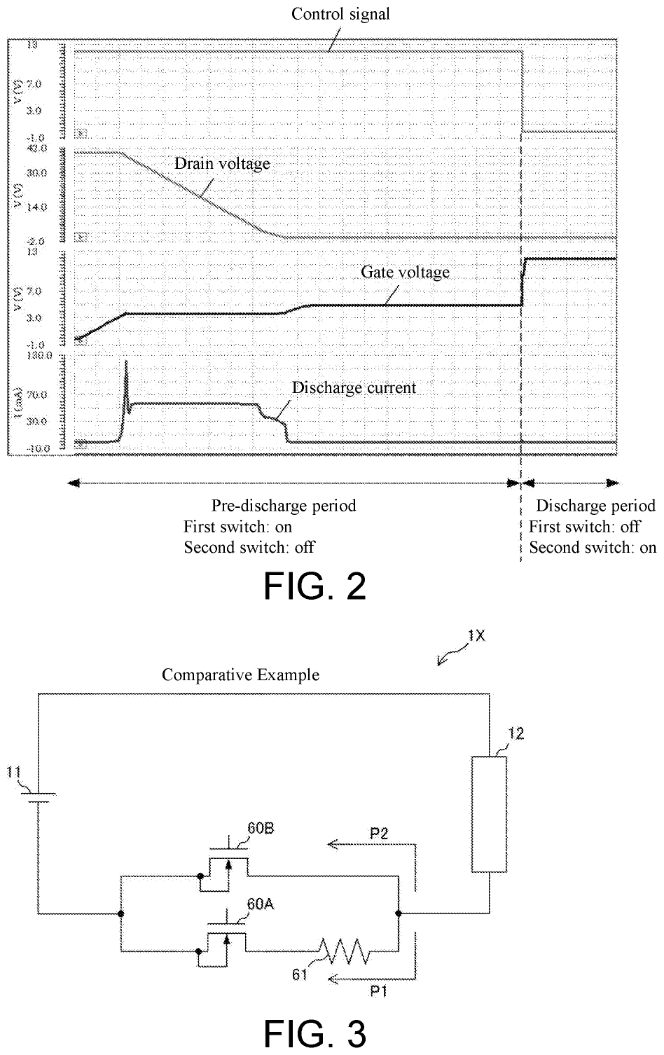

FIG. 2 is a diagram showing the operation waveforms of various parts obtained by an operation simulation performed on the load driving system 1. FIG. 2 shows the changes over time of the control signal S_{C}, the drain voltage and gate voltage of the transistor 13, and the discharge current.

When power is supplied to the capacitive load 12, the switching control circuit 40 outputs a high-level control signal S_{C}. Thus, the first switch 23 is set to the on state and the second switch 32 is set to the off state. As a result, the first gate voltage V_{G1} output from the first gate voltage output circuit 20 is supplied to the gate of the transistor 13. When the level of the first gate voltage V_{G1} rises and reaches the threshold level of the transistor 13, the transistor 13 is set to the on state, and the charge accumulated in the capacitive load 12 starts to be discharged. The period in which the first gate voltage V_{G1} is supplied to the gate of the transistor 13 is a pre-discharge period in which the charge accumulated in the capacitive load 12 starts to be discharged.

The discharge current generated due to discharge of the charge accumulated in the capacitive load 12 flows through the path from the capacitive load 12 to the negative electrode of the power supply 11 via the transistor 13 and the current detection resistor 14. As the discharge current flows through the current detection resistor 14, a voltage is generated across both ends of the current detection resistor 14, and this voltage is input to the current detection terminal 15. The first gate voltage output circuit 20 controls the first gate voltage V_{G1} so that the difference between the terminal voltage of the current detection resistor 14 input to the current detection terminal 15 and the reference voltage V_{ref} is constant. In other words, the first gate voltage output circuit 20 controls the first gate voltage V_{G1} so that the discharge current flowing through the transistor 13 is constant. By controlling the discharge current to be constant in this manner, it is possible to suppress an inrush current from being generated due to discharge of the capacitive load 12. According to the simulation result shown in FIG. 2, the peak value of the inrush current was suppressed to about 120 mA.

As the charge accumulated in the capacitive load 12 is discharged, the drain voltage of the transistor 13 decreases. When the discharge is completed, the discharge current becomes substantially zero, and the drain voltage of the transistor 13 becomes substantially zero. After the discharge is completed, the switching control circuit 40 outputs a low-level control signal S_{C}. Thus, the first switch 23 is set to the off state and the second switch 32 is set to the on state. As a result, the second gate voltage V_{G2} output from the second gate voltage output circuit 30 is supplied to the gate of the transistor 13. The second gate voltage output circuit 30 outputs a voltage at a constant level higher than the level of the first gate voltage V_{G1} after completion of discharging the capacitive load 12 as the second gate voltage V_{G2}, and supplies the voltage to the gate of the transistor 13. Thus, the on state of the transistor 13 is maintained. The on-resistance of the transistor 13 when the second gate voltage V_{G2} is supplied is lower than the on-resistance of the transistor 13 when the first gate voltage V_{G1} is supplied. By reducing the on-resistance of the transistor, power can be supplied to the capacitive load 12 with low loss. The period in which the second gate voltage V_{G2} is supplied to the gate of the transistor 13 is a discharge period in which power is continued to be supplied to the capacitive load 12 after the capacitive load 12 is discharged.

FIG. 3 is a diagram showing an example of the configuration of a load driving system 1X according to a comparative example. The load driving system 1X according to the comparative example has a first discharge path P1 including a current limiting resistor 61 and a transistor 60A, and a second discharge path P2 including a transistor 60B. In the pre-discharge period immediately after power starts to be supplied to the capacitive load 12, the transistor 60A is set to the on state and the transistor 60B is set to the off state. Thus, the capacitive load 12 is connected to the first discharge path P1, and a discharge current generated due to discharge of the charge accumulated in the capacitive load 12 flows to the first discharge path P1. An inrush current is suppressed by the current limiting resistor 61 provided in the first discharge path P1. In the subsequent discharge period, the transistor 60A is set to the off state and the transistor 60B is set to the on state. Thus, the capacitive load 12 is connected to the second discharge path P2, and power is supplied to the capacitive load 12 using the second discharge path P2 with low resistance.

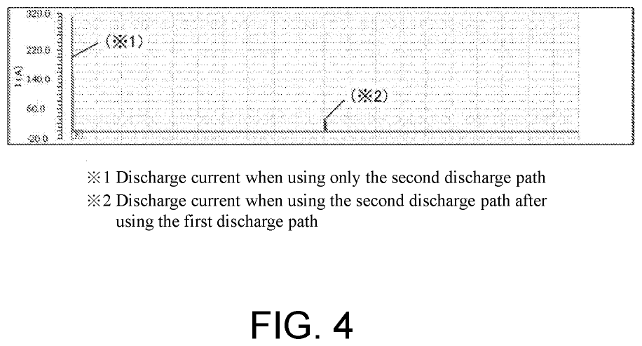

FIG. 4 is a diagram showing the operation waveforms of various parts obtained by an operation simulation performed on the load driving system 1X according to the comparative example. FIG. 4 shows the discharge current when the charge accumulated in the capacitive load 12 was discharged using only the second discharge path P2, and the discharge current when the charge was discharged using the second discharge path P2 after using the first discharge path P1. When the charge accumulated in the capacitive load 12 was discharged using only the second discharge path P2, the peak value of the inrush current was 310 A. On the other hand, when the charge accumulated in the capacitive load 12 was discharged using the second discharge path P2 after using the first discharge path P1, the peak value of the inrush current was 33 A. That is, by performing pre-discharge using the first discharge path P1, the peak value of the inrush current could be suppressed to about 1/10 of that in the case of performing discharge using only the second discharge path P2. However, according to this configuration, a transistor is required for each of the first discharge path P1 and the second discharge path P2, which leads to an increase in cost.

In contrast, with the discharge control circuit 10 according to the embodiment of the disclosed technology, the gate voltage supplied to the transistor 13 is switched to switch the on-resistance of the transistor 13 and thereby switch the electrical resistance on the discharge path, so the number of transistors provided on the discharge path can be reduced to one. Furthermore, with the discharge control circuit 10 according to the present embodiment, the first gate voltage output circuit 20 controls the first gate voltage V_{G1} so that the discharge current flowing through the transistor 13 is constant, so the inrush current can be effectively suppressed.

Regarding the above embodiment, the following additional notes are further disclosed.

### (Additional Note 1)

A discharge control circuit, including:
a first gate voltage output circuit configured to output a first gate voltage supplied to a transistor connected to a capacitive load;
a second gate voltage output circuit configured to output a second gate voltage supplied to the transistor; and
a switching control circuit configured to switch supply of the first gate voltage and the second gate voltage to the transistor,
wherein the first gate voltage output circuit is configured to control the first gate voltage so that a current flowing through the transistor is constant,
the second gate voltage output circuit is configured to output a voltage at a constant level as the second gate voltage, and
the switching control circuit is configured to perform control to supply the second gate voltage after supplying the first gate voltage to the transistor.

### (Additional Note 2)

The discharge control circuit according to additional note 1, wherein the first gate voltage output circuit is configured to control the first gate voltage so that a difference between a terminal voltage of a current detection resistor that detects the current flowing through the transistor and a predetermined reference voltage is constant.

### (Additional Note 3)

The discharge control circuit according to additional note 2, wherein the first gate voltage output circuit includes a differential amplifier circuit in which the terminal voltage of the current detection resistor is input to an inverting input terminal and the reference voltage is input to a non-inverting input terminal.

### (Additional Note 4)

The discharge control circuit according to any one of additional notes 1 to 3, wherein a level of the second gate voltage is higher than a level of the first gate voltage.

What is claimed is:

1. A discharge control circuit, comprising:
a first gate voltage output circuit configured to output a first gate voltage supplied to a transistor connected to a capacitive load;
a second gate voltage output circuit configured to output a second gate voltage supplied to the transistor; and
a switching control circuit configured to switch supply of the first gate voltage and the second gate voltage to the transistor,
wherein the first gate voltage output circuit is configured to control the first gate voltage so that a current flowing through the transistor is constant,
the second gate voltage output circuit is configured to output a voltage at a constant level as the second gate voltage, and
the switching control circuit is configured to perform control to supply the second gate voltage after supplying the first gate voltage to the transistor.

2. The discharge control circuit according to claim 1, wherein the first gate voltage output circuit is configured to control the first gate voltage so that a difference between a terminal voltage of a current detection resistor that detects the current flowing through the transistor and a predetermined reference voltage is constant.

3. The discharge control circuit according to claim 2, wherein the first gate voltage output circuit comprises a differential amplifier circuit in which the terminal voltage of the current detection resistor is input to an inverting input terminal and the reference voltage is input to a non-inverting input terminal.

4. The discharge control circuit according to claim 1, wherein a level of the second gate voltage is higher than a level of the first gate voltage.

5. The discharge control circuit according to claim 2, wherein a level of the second gate voltage is higher than a level of the first gate voltage.

6. The discharge control circuit according to claim 3, wherein a level of the second gate voltage is higher than a level of the first gate voltage.
